(19) United States
(12) Patent Application Publication
(10) Pub. No.: US 2025/0341558 A1
(43) Pub. Date: Nov. 6, 2025

(54) FAULT LOCATION DETERMINATION

(71) Applicant: Florida Power & Light Company, Juno Beach, FL (US)

(72) Inventors: Kathryn A. Stutin, Plantation, FL (US); Guillermo Aleman, Miami, FL (US); Vivian Garcia, Palm Beach Gardens, FL (US); Eliud Perez, Royal Palm Beach, FL (US)

(21) Appl. No.: 18/652,267

(22) Filed: May 1, 2024

(51) Int. Cl. G01R 31/08

(52) U.S. Cl. CPC G01R 31/088; G01R 31/085

(57) ABSTRACT

In a described example, a method can include receiving a first voltage measurement, a second voltage measurement, and a third voltage measurement from a first sensor, a second sensor, and a third sensor, respectively. The voltage measurements can be root mean square (RMS) voltage measurements, for example. The first, second, and third sensors are located respectively at a first location, a second location, and a third location along a power feeder line. The method can include analyzing a first decay rate between the first voltage measurement and the second voltage measurement, analyzing a second decay rate between the second voltage measurement and the third voltage measurement, and determining a fault location at a location between the first location and the second location based on the second decay rate being less than the first decay rate.

### TECHNICAL FIELD

This description relates to systems and methods for fault location determination.

### BACKGROUND

A smart meter is an electronic device that records information such as consumption of electric energy, voltage levels, current and power factor. Smart meters communicate the information to electricity suppliers for system monitoring and customer billing. Smart meters record energy in real-time, and report regularly, for short intervals throughout the day. Smart meters enable two-way communication between the meter and the central system. Such an advanced metering infrastructure differs from automatic meter reading in that it enables two-way communication between the meter and the supplier. Communications from the meter to the network may be wireless, or via fixed wired connections such as a power line carrier. Wireless communication options in common use include cellular communications, Wi-Fi, wireless ad hoc networks over Wi-Fi, wireless mesh networks, low power long-range wireless (LoRa), Wize (high radio penetration rate, open, using the frequency 169 MHz) ZigBee (low power, low data rate wireless), and Wi-SUN (Smart Utility Networks).

### SUMMARY

In a described example, a method can include receiving a first voltage measurement, a second voltage measurement, and a third voltage measurement from a first sensor, a second sensor, and a third sensor, respectively. The first, second, and third sensors are located respectively at a first location, a second location, and a third location along a power feeder line. The method can include analyzing a first decay rate between the first voltage measurement and the second voltage measurement, analyzing a second decay rate between the second voltage measurement and the third voltage measurement, and determining a fault location of a fault along the power feeder line at a location between the first location and the second location based on the second decay rate being less than the first decay rate.

In a described example, a method can include receiving a plurality of root mean square (RMS) voltage measurements from a respective plurality of voltage sensors along a respective plurality of locations along a power feeder line in response to a fault on the power feeder line and evaluating the plurality of RMS voltage measurements at each of the locations of the voltage sensors to determine a location of the fault between a pair of the voltage sensors based on a relative rate of decay of the RMS voltage measurements between each successive pair of the voltage sensors along the power feeder line.

In a described example, a system can include a power feeder line, a plurality of voltage sensors, a receiver, and a controller. The plurality of voltage sensors are located along a respective plurality of locations along the power feeder line. Each voltage sensor includes a communication circuit. The receiver is configured to receive a root mean square (RMS) voltage measurement from each of the voltage sensors in response to a fault on the power feeder line. The controller is configured to evaluate the RMS voltage measurement at each of the locations of the voltage sensors and to determine a location of the fault between a pair of the voltage sensors based on a relative rate of decay of the RMS voltage measurements between each successive pair of the voltage sensors along the power feeder line.

### BRIEF DESCRIPTION OF THE DRAWINGS

FIG. 1 is an illustration of an example utility power system.

FIG. 2 is an example of a component diagram of a sensor for fault location determination.

FIG. 3 is an example of a diagram illustrating a system for fault location determination.

FIG. 4 is an example of a graph of voltages corresponding to sensor locations of an electrical network.

FIG. 5 is an example of a table of voltages corresponding to the sensor locations of the electrical network of FIG. 4.

FIG. 6 is an example of a flow diagram of a method for fault location determination.

FIG. 7 is an example of a flow diagram of a method for fault location determination.

### DETAILED DESCRIPTION

This description relates to systems and methods for fault location determination. According to one example, sensors located along a power feeder line are configured to operate, even during an outage or during loss of power supplied to the sensors. In the event of an outage or when supplied power is below a predetermined threshold (e.g., a blackout or a brownout), an energy storage element, such as a capacitor, for example, can be discharged to power a communication circuit of the sensor in order to transmit data to facilitate fault location determination, such as a voltage measurement (e.g., root mean square (RMS) voltage measurement or instantaneous voltage measurement). In this way, sensors located along a set of locations of the power feeder line can measure a respective set of voltages during power outage scenarios and transmit these voltage measurements to a system for fault location determination.

Fault location determination is provided by analyzing successive rates of decay between pairs of voltage measurements and determining a fault location based on a comparison between decay rates. For example, the system for fault location determination can analyze a first decay rate between the first voltage measurement and the second voltage measurement, analyze a second decay rate between the second voltage measurement and the third voltage measurement, and determine the fault location at a location between the first location and the second location based on the second decay rate being less than the first decay rate. In this way, fault location determination is provided in a manner such that merely a single voltage measurement upstream of the fault is utilized to pinpoint the fault location. Further, no network models, voltage phasor measurements, or current measurements are required. A network model can be computationally expensive to manage while sensors capable of measuring voltage phasors generally cost more than other types of less sophisticated voltage sensors.

In this way, the fault location determination provided herein offers the advantages of efficiency and scalability. For example, the use of RMS voltage measurements or instantaneous voltage measurements rather than the network models, voltage phasor measurements, and current measurements enables quicker identification of the fault location, thereby enabling the troubleshooting and repair process to be more efficient, reducing downtime and minimizing the impact on customer outages. Additionally, the fault location determination provided herein supports scalability by utilizing a higher number of sensors. For example, as the number of sensors increases, the precision of fault location identification improves, thereby allowing for accurate fault identification in large-scale electrical systems.

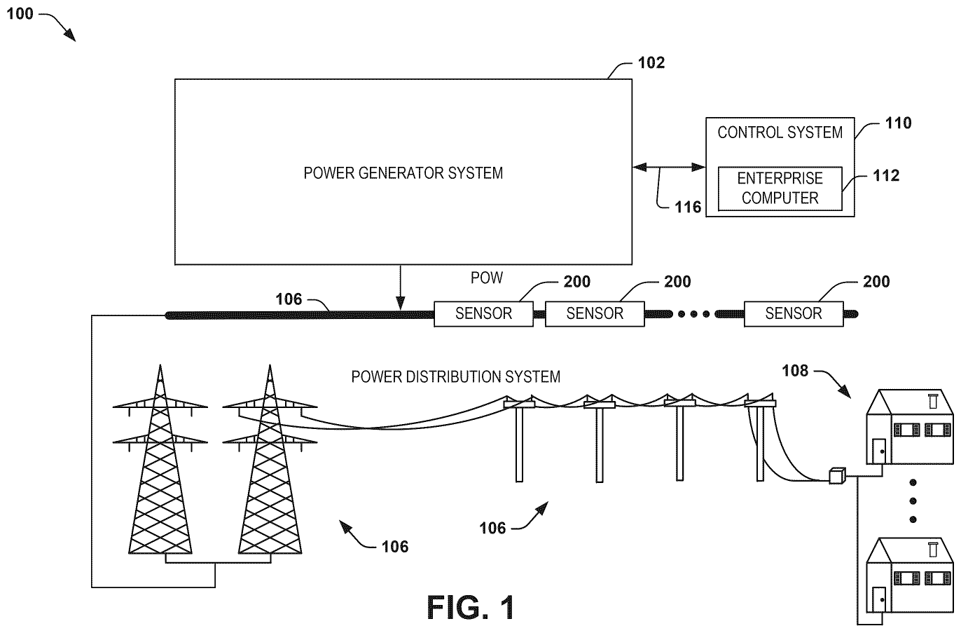

FIG. 1 is an illustration of an example utility power system. The utility power system 100 includes a power generator system 102 that is configured to provide power, demonstrated in the example of FIG. 1 as POW, to a power transmission system 104. The power transmission system 104 can correspond to a power bus or one or more points-of-interconnect (POIs) that provide power via a power distribution system 106 (e.g., transformers, substations, and power lines) to consumers, demonstrated generally at 108. In the example of FIG. 1, the power generator system 102 is demonstrated as being controlled by a control system 110. The control system 110 can include an enterprise computer system 112, such as a Supervisory Control and Data Acquisition (SCADA) computer, which allows users at a local or remote location to monitor and control the operation of the power generator system 102. The power generator system 102 can include any type of power generating equipment (e.g., wind turbines, solar panels, geothermal power generators, hydroelectric power generators, fossil fuel power plants, etc.).

The enterprise computer system 112 can communicate with the power generating equipment to monitor performance of and provide control of the power generating equipment via communication lines, demonstrated generally at 116. Additionally, the power distribution system 106 can be equipped with sensors 200, which are configured to detect voltage measurements at respective locations. The sensors 200 can provide the voltage measurements to the enterprise computer system 112 via the communication lines 116, thereby enabling the enterprise computer system 112 to determine an approximate location of a fault, such as identifying that the fault occurred between a set of two of the voltage sensors 200. Therefore, users at the control system 110 can identify the approximate location of the fault more rapidly than by inspecting along the entire length of the power distribution system 106, thereby allowing repairs to be provided more quickly.

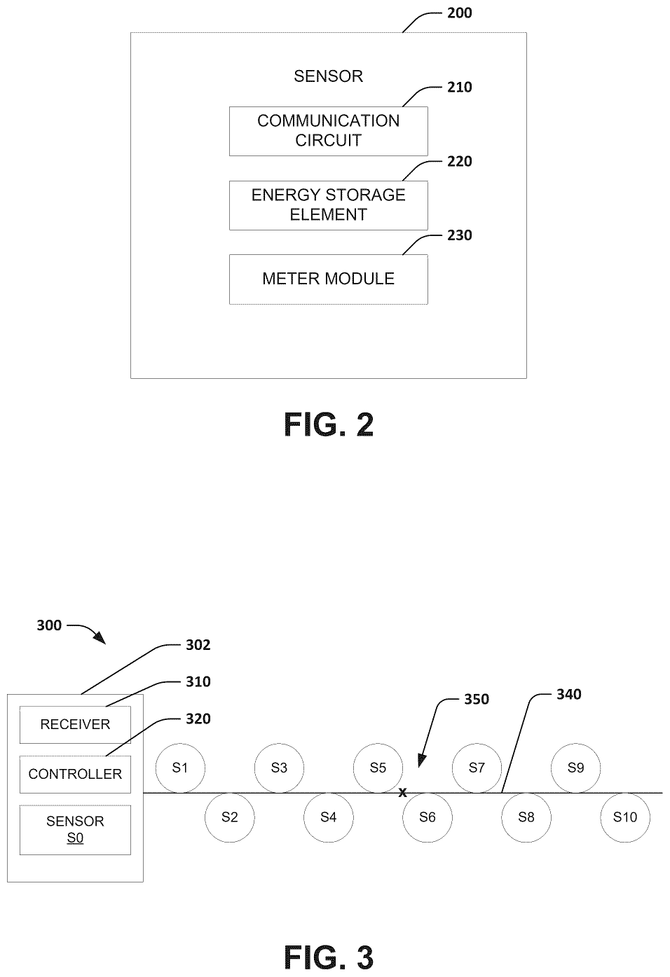

FIG. 2 is an example of a component diagram of a sensor 200 for fault location determination. The sensor 200 of FIG. 2 can include a communication circuit 210, an energy storage element 220, and a meter module 230. According to one example, the sensor 200 can be configured to have fault ride-through capability and be located along a power feeder line. In other words, when a fault occurs on the power feeder line, sensors, such as the sensor 200, are configured to remain stable and continue to otherwise operate during the fault and/or other disturbances. For example, during the fault, the energy storage element 220 is configured to supply energy to the communication circuit 210 and the meter module 230.

The meter module 230 is configured to provide a voltage measurement, such as an RMS voltage measurement or an instantaneous voltage measurement, associated with the sensor 200 at a location along the power feeder line. RMS voltage measurements can be used because the RMS value is the effective value of an alternating current (AC) voltage. It will be appreciated that a plurality of sensors can be located at a respective plurality of locations along the power feeder line and that the plurality of sensors can be configured to provide a respective plurality of voltage measurements. The communication circuit 210 can include a transceiver, for example, and can transmit the voltage measurement taken by the meter module 230 of the sensor 200 to a receiver of a system for fault location determination, even in the event of the fault or disturbance. Additionally, the communication circuit 210 can transmit a sensor identifier (e.g., including a sensor location, a sensor ID, etc.) associated with the sensor 200 to the receiver to facilitate fault location determination. In this way, the sensor 200 of FIG. 2 can provide fault ride-through voltage measurements.

FIG. 3 is an example of a diagram illustrating a system 300 for fault location determination. According to one example, the system 300 for fault location determination can be implemented at a feeder head 302. The system 300 for fault location determination can include a receiver 310, a controller 320, and a sensor S0. The sensor S0 can be configured similarly to the sensor 200 of FIG. 2. For example, the sensor S0 can provide a voltage measurement, such as an RMS voltage measurement, associated with the sensor S0 at a location associated with the feeder head 302. For example, the feeder head 302 can be located at a location (e.g., a zeroth location) along a power feeder line 340. The feeder head 302 is a connection point between a substation and a feeder. Distribution stations can include one or more feeders. A substation can be a distribution substation, which is subset of substations that provide distribution level voltages. Additionally, a plurality of sensors, such as sensors S1-S10 are located at a first location, a second location, a third location, a fourth location, a fifth location, a sixth location, a seventh location, an eighth location, a ninth location, and a tenth location, respectively along the power feeder line 340. It will be appreciated that the locations of the sensors S1-S10 are not necessarily required to be equidistant from one another. In the example of FIG. 3, a fault 350 or disturbance is located between sensors S5-S6 and between the fifth location and the sixth location.

The receiver 310 can be configured to receive a voltage measurement (e.g., RMS voltage measurement) and a sensor identifier associated with the corresponding voltage sensor from a communication circuit (e.g., communication circuit 210 of the sensor 200 of FIG. 2) of each of the voltage sensors S1-S10 in response to any fault on the power feeder line 340.

The controller 320 is configured to evaluate the voltage measurement (e.g., RMS voltage measurement) at each of the locations of the voltage sensors S1-S10 (e.g., first location-tenth location, etc.) and to determine a location of the fault 350 between a pair of the voltage sensors (e.g., S5-S6 in FIG. 3) based on a relative rate of decay of the voltage measurements between each successive pair of the voltage sensors along the power feeder line 340 and based on the sensor identifiers. In other words, the controller 320 analyzes the voltage measurements from sensors S1-S10 to determine changes in the voltage decay between pairs of sensors (e.g., S1-S2, S2-S3, S3-S4, etc.) which are adjacent to one another. The changes in the voltage decay can correspond to a decreasing gradient or slope in amplitude of the RMS voltage measurements. In this way, the controller 320 can be configured to identify a point where the slope of the voltage decay flattens out (e.g., where the rate of change levels off), and determine the location of the fault between two sensors accordingly.

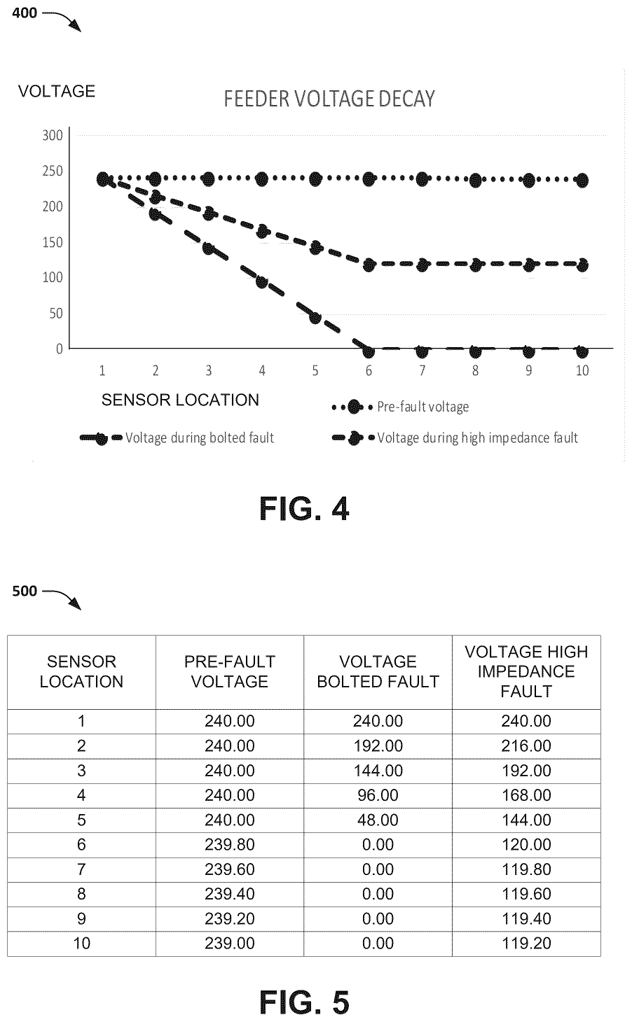

An example of fault determination is demonstrated in the examples of FIGS. 4 and 5. FIG. 4 is an example of a graph 400 of voltages corresponding to sensor locations of an electrical network. FIG. 5 is an example of a table 500 of voltage data or voltage measurements corresponding to the sensor locations of the electrical network of FIG. 4. The values associated with the voltage measurements for different scenarios (e.g., pre-fault, bolted fault condition, high-impedance fault condition) are provided in the table 500 of FIG. 5. A bolted fault condition is a hard ground or hard phase to phase fault with no impedance between the phase and ground at the fault location, or between the phases at the fault location. A high-impedance fault means there is a component adding additional impedance to the fault at the location of the fault (e.g., a tree, a burning pole, etc.). This impedance provides some isolation from ground or the other phase at the fault location.

The graph 400 of FIG. 4 illustrates ten voltage measurements for ten respective sensors S1-S10 located at the first location through the tenth location, respectively. For example, the x-axis represents sensor locations along the power feeder line in order of proximity from a feeder head. The y-axis represents the voltage values (e.g., voltage measurements) recorded by the sensors S1-S10. As seen in FIG. 4, the pre-fault voltage measurements across all ten sensors S1-S10 is steady, with no change in slope.

An occurrence of a fault (e.g., an unplanned event, such as a short circuit or open circuit) in the power system can cause a voltage decay along the power feeder line. For example, the voltage measurements across the ten sensors S1-S10 during the bolted fault condition and the high-impedance fault condition results in a successive voltage drop seen from sensors S1-S6 and a relatively flat voltage change between sensors S7-S10, for example. As discussed, sensors, such as the sensor 200 can be configured to provide voltage data or voltage measurements during the fault event in real time since the sensor 200 has fault ride-through capability. In this way, the graph 400 visualizes the concept of identifying the fault location by observing the point where the slope of the voltage decay flattens (e.g., by identifying two voltage measurements downstream of the fault where the voltage decay between the two voltage measurements is less than a threshold). Explained another way, the fault location can be identified when the slope of two corresponding voltage measurements for two sensors is less than the threshold (e.g., a near zero number).

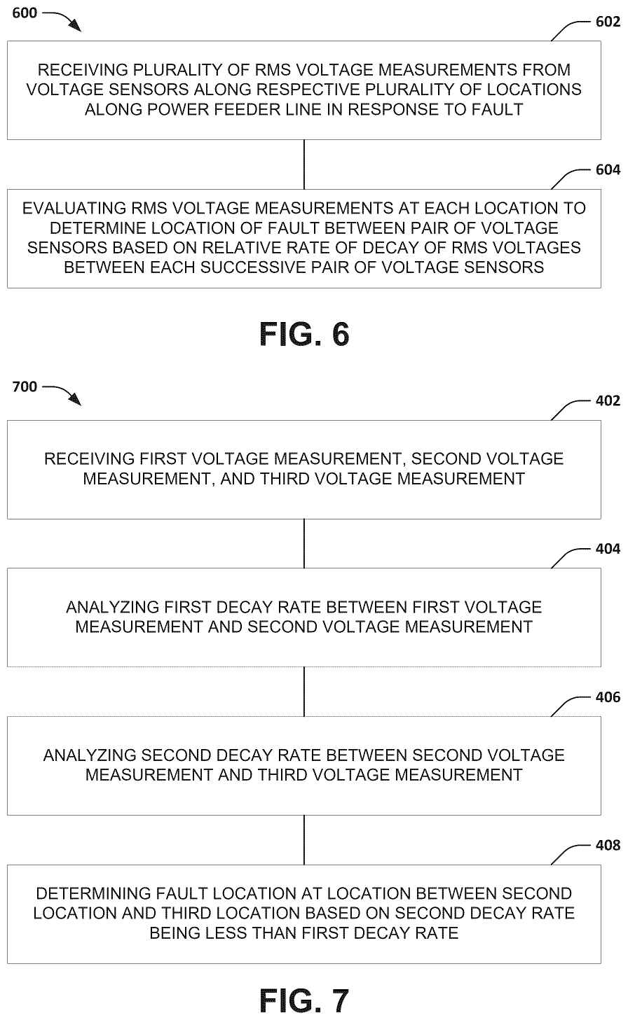

FIG. 6 is an example of a flow diagram of a method 600 for fault location determination. In a described example, the method 600 can include receiving 602 a plurality of RMS voltage measurements from a respective plurality of voltage sensors along a respective plurality of locations along a power feeder line in response to a fault on the power feeder line and evaluating 604 the plurality of RMS voltage measurements at each of the locations of the voltage sensors to determine a location of the fault between a pair of the voltage sensors based on a relative rate of decay of the RMS voltage measurements between each successive pair of the voltage sensors along the power feeder line.

FIG. 7 is an example of a flow diagram of a method 700 for fault location determination. In a described example, the method 700 can include receiving 702 a first voltage measurement, a second voltage measurement, and a third voltage measurement from a first sensor, a second sensor, and a third sensor, respectively. The first, second, and third sensors can be located respectively at a first location, a second location, and a third location along a power feeder line. The method 700 can include analyzing 704 a first decay rate between the first voltage measurement and the second voltage measurement, analyzing 706 a second decay rate between the second voltage measurement and the third voltage measurement, and determining 708 a fault location at a location between the first location and the second location based on the second decay rate being less than the first decay rate.

With reference to FIGS. 2-5 and to the method 600 above, the method can include receiving a plurality of RMS voltage measurements from a respective plurality of voltage sensors (e.g., sensors S5-S7) along a respective plurality of locations along the power feeder line 340 in response to the fault 350 on the power feeder line 340 and evaluating the plurality of RMS voltage measurements at each of the locations of the voltage sensors (e.g., sensors S5-S7) to determine the location of the fault between a pair of the voltage sensors based on a relative rate of decay of the RMS voltage measurements between each successive pair (e.g., S5-S6 or S6-S7) of the voltage sensors along the power feeder line. Again, the relative rate of decay for the first pair of sensors (S5-S6) is greater than the relative rate of decay for the second pair of sensors (S6-S7). Therefore, the controller 320 can identify the fault location to be at a location between the sensors S5-S6 based on these relative rates of decay for the different sensor pairs.

With reference to FIGS. 2-5 and to the method 700 above, the method can, for example, include receiving a first voltage measurement from sensor S5, a second voltage measurement from sensor S6, and a third voltage measurement from sensor S7, respectively. Sensor S5 can be disposed at a first location, sensor S6 at a second location, and sensor S7 at a third location along the power feeder line 340. Additionally, the method can include analyzing a first decay rate between the first voltage measurement and the second voltage measurement of sensors S5-S6, analyzing a second decay rate between the second voltage measurement and the third voltage measurement of sensors S6-S7. As seen from the table 500 of FIG. 5, the voltage measurement from sensor S5 is 48.00 (for the bolted voltage fault condition) and the voltage measurement from sensor S6 is 0.00, and the voltage measurement from sensor S7 is 0.00. Therefore, assuming that the distance between sensors S5-S6-S7 is a constant k, the first decay rate is 48.00/k while the second decay rate is zero/k (i.e., 0). Therefore, the controller 320 can determine the fault location to be at a location between the sensors S5-S6 based on the second decay rate (e.g., 0) being less than the first decay rate (e.g., 48.00/k).

In this description, the term “couple” can cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

In this description, a device that is “configured to” perform a task or function can be configured (e.g., programmed and/or hardwired) at a time of manufacturing by a manufacturer to perform the function and/or can be configurable (or reconfigurable) by a user after manufacturing to perform the function and/or other additional or alternative functions. The configuring can be through firmware and/or software programming of the device, through a construction and/or layout of hardware components and interconnections of the device, or a combination thereof. Furthermore, a circuit or device that is described herein as including certain components can instead be configured to couple to those components to form the described circuitry or device. For example, a structure described herein as including one or more semiconductor elements (such as transistors), one or more passive elements (such as resistors, capacitors, and/or inductors), and/or one or more sources (such as voltage and/or current sources) can instead include only the semiconductor elements within a single physical device (e.g., a semiconductor die and/or integrated circuit (IC) package) and can be configured to couple to at least some of the passive elements and/or the sources to form the described structure, either at a time of manufacture or after a time of manufacture, such as by an end-user and/or a third-party.

The phrase “based on” means “based at least in part on”. Therefore, if X is based on Y, X can be a function of Y and any number of other factors.

Modifications are possible in the described embodiments, and other embodiments are possible, within the scope of the claims.

What is claimed is:

1. A method, comprising:
receiving a first voltage measurement, a second voltage measurement, and a third voltage measurement from a first sensor, a second sensor, and a third sensor, respectively, wherein the first, second, and third sensors are located respectively at a first location, a second location, and a third location along a power feeder line;
analyzing a first decay rate between the first voltage measurement and the second voltage measurement;
analyzing a second decay rate between the second voltage measurement and the third voltage measurement; and
determining a fault location of a fault along the power feeder line at a location between the first location and the second location based on the second decay rate being less than the first decay rate.

2. The method of claim 1, wherein the first voltage measurement, the second voltage measurement, and the third voltage measurement are root mean square (RMS) voltage measurements.

3. The method of claim 1, wherein the fault location is determined based on the second decay rate being less than a threshold.

4. The method of claim 3, wherein the threshold is a near-zero number.

5. The method of claim 1, wherein the first location is upstream of the fault and the second and third locations are downstream of the fault.

6. The method of claim 1, wherein the first, second, and third voltage measurements each include sensor identification information.

7. The method of claim 1, comprising supplying power to the first, second, and third sensors in response to the fault on the power feeder line.

8. The method of claim 1, wherein the first decay rate and the second decay rate are calculated as slopes.

9. The method of claim 1, wherein the fault is a bolted fault or a high-impedance fault.

10. The method of claim 1, wherein the first sensor is located on a feeder head.

11. A method, comprising:
receiving a plurality of root mean square (RMS) voltage measurements from a respective plurality of voltage sensors along a respective plurality of locations along a power feeder line in response to a fault on the power feeder line; and
evaluating the plurality of RMS voltage measurements at each of the locations of the voltage sensors to determine a location of the fault between a pair of the voltage sensors based on a relative rate of decay of the RMS voltage measurements between each successive pair of the voltage sensors along the power feeder line.

12. The method of claim 11, wherein each of the plurality of root mean square (RMS) voltage measurements includes sensor identification information.

13. The method of claim 11, comprising supplying power to the plurality of voltage sensors in response to the fault on the power feeder line.

14. The method of claim 11, wherein the location of the fault is determined based on the relative rate of decay being a near-zero number.

15. The method of claim 11, wherein the fault is a bolted fault or a high-impedance fault.

16. A system, comprising:
a power feeder line;
a plurality of voltage sensors along a respective plurality of locations along the power feeder line, each voltage sensor comprising a communication circuit;
a receiver configured to receive a root mean square (RMS) voltage measurement from each of the voltage sensors in response to a fault on the power feeder line; and
a controller configured to evaluate the RMS voltage measurement at each of the locations of the voltage sensors and to determine a location of the fault between a pair of the voltage sensors based on a relative rate of decay of the RMS voltage measurements between each successive pair of the voltage sensors along the power feeder line.

17. The system of claim 16, wherein the communication circuit of each voltage sensor is configured to transmit the RMS voltage measurement to the receiver.

18. The system of claim 16, wherein the communication circuit of each voltage sensor is configured to transmit a sensor identifier associated with the corresponding voltage sensor to the receiver and the controller determines the location of the fault based on the sensor identifier.

19. The system of claim 16, wherein each voltage sensor includes an energy storage element configured to supply power to the communication circuit in response to the fault on the power feeder line.

20. The system of claim 16, wherein a first sensor of the plurality of voltage sensors is located on a feeder head.
